(19) United States
(12) Patent Application Publication
(10) Pub. No.: US 2015/0116054 A1
(43) Pub. Date: Apr. 30, 2015

(54) APPARATUS AND SYSTEMS FOR FILTERING FOR POWER LINE COMMUNICATION

(71) Applicant: SunEdison Inc., Maryland Heights, MO (US)

(72) Inventor: Aner Tennen, Sunnyvale, CA (US)

(21) Appl. No.: 14/525,966

(22) Filed: Oct. 28, 2014

Related U.S. Application Data
(60) Provisional application No. 61/898,168, filed on Oct. 31, 2013.

(51) Int. Cl. H03H 7/01

(52) U.S. Cl. CPC H03H 7/0161; H03H 7/06
USPC 333/181; 333/185

(57) ABSTRACT

Apparatus, methods, and systems for filtering for power line communications are described. In one example, a low pass filter for power line communication in a power system including at least one phase conductor and a neutral conductor is described. The filter includes at least one capacitor coupled between the phase conductor and the neutral conductor, at least one resistor coupled between the phase conductor and the neutral conductor, and at least one inductor coupled on the neutral conductor.

### CROSS REFERENCE TO RELATED APPLICATIONS

This application claims priority to U.S. Provisional Application No. 61/898,168 filed Oct. 31, 2013, the entire disclosure of which is hereby incorporated by reference in its entirety.

### FIELD

The field of the disclosure relates generally to electronic filtering. More particularly, this disclosure relates to apparatus, methods, and systems for filtering for power line communication.

### BACKGROUND

Power line communication (PLC) uses electric power distribution conductors to carry data. The power distribution conductors simultaneously carry electric power (typically alternating current (AC) power) and data transmitted using a PLC system. Generally, PLC systems utilize a modulated carrier signal applied to the distribution conductor to carry data that is to be transmitted using the PLC system. The power distribution conductors on which PLC data is transmitted are often electrically noisy environments. Noise may be introduced to the distribution conductors through equipment (such as electric motors and switching power supplies) connected to the distribution conductors and/or through non-contact, field coupled induction onto the distribution conductors (such as from radar, television, and/or radio transmissions).

PLC systems often utilize one or more filters on the power distribution conductors to attempt to reduce the amount of noise seen by the PLC system. Typically, the filters utilized by known systems are low pass filters that block relatively high frequency signals and permit low frequency signals (such as 50/60 Hertz (Hz) AC current) to pass freely. At least some of these known filters include an inductor attached to each conductor of the power distribution system (including each phase and neutral in a multi-phase system). Each inductor is required to carry the full current that may pass through the conductor to which it is coupled. Due to the requirement to pass potentially heavy AC current in all conductors, combined with the requirement to utilize all or some of the conductors as a communication medium, the inductors used in such filters generally use very heavy and expensive magnetic cores that will not saturate under the very high AC currents that are likely to be present. Moreover, some known PLC systems utilize a relatively low frequency band (e.g., 70 kHz-150 kHz) that requires a corner frequency of about 20-30 kHz and at least 2^{nd} or 3^{rd} order low pass filter in order to achieve a desired 30 dB of attenuation. Thus, some known filters utilize relatively large inductors (in the range of 50 μH and above) with very large magnetic cores to sustain the high AC current and accommodate thick AC conductors (8-AWG and below). Additionally, in multi-phase systems the inductor magnetic core must be sized to receive several conductors wound on the same core. As a result, at least some known PLC filters are very bulky and expensive.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION

In one aspect, a low pass filter for power line communication in a power system including at least one phase conductor and a neutral conductor is described. The filter includes at least one capacitor coupled between the phase conductor and the neutral conductor, at least one resistor AC coupled (through capacitive coupling) between the phase conductor and the neutral conductor, and at least one inductor coupled on the neutral conductor.

Another aspect of this disclosure is a power line communication (PLC) system. The PLC system includes a low pass filter configured for coupling between the PLC system and an alternating current (AC) grid. The low pass filter is configured to create a relatively quiet line for PLC communication on a neutral conductor that does not carry AC current and to substantially isolate the PLC system from noise content of the AC grid.

Yet another aspect of the disclosure is a power line communication (PLC) system including a low pass filter configured for coupling between the PLC system and an alternating current (AC) grid. The low pass filter is configured to substantially isolate the PLC system from noise content of the AC grid and to provide a fifty ohm termination for the PLC system.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a perspective view of an example photovoltaic (PV) module;

FIG. 2 is a cross-sectional view of the PV module shown in FIG. 1 taken along the line A-A;

FIG. 3 is a block diagram of an example computing device;

FIG. 4 is a block diagram of an example PV Solar system;

FIG. 5 is circuit diagram of an example PLC filter;

FIG. 6 is an example ferrite bead for use with the PLC filter shown in FIG. 5; and

FIG. 7 is a graph of the simulated frequency response of the PLC filter shown in FIG. 5.

Like reference symbols in the various drawings indicate like elements.

### DETAILED DESCRIPTION

The embodiments described herein generally relate to electronic filtering. More particularly, embodiments described herein relate to apparatus, methods, and systems for filtering for power line communication (PLC). Still more particularly, some embodiments described herein relate to filters for PLC in photovoltaic (PV) alternating current (AC) solar systems.

PV modules (also known as solar modules) convert solar energy into electrical energy. The electrical energy may be used directly at the site, converted for local use, and/or converted and transmitted to an electrical grid or another destination. Typically, a PV installation includes at least a plurality of PV modules logically or physically grouped together to form an array and one or more inverters that convert the direct current (DC) output of the PV modules to alternating current (AC) power.

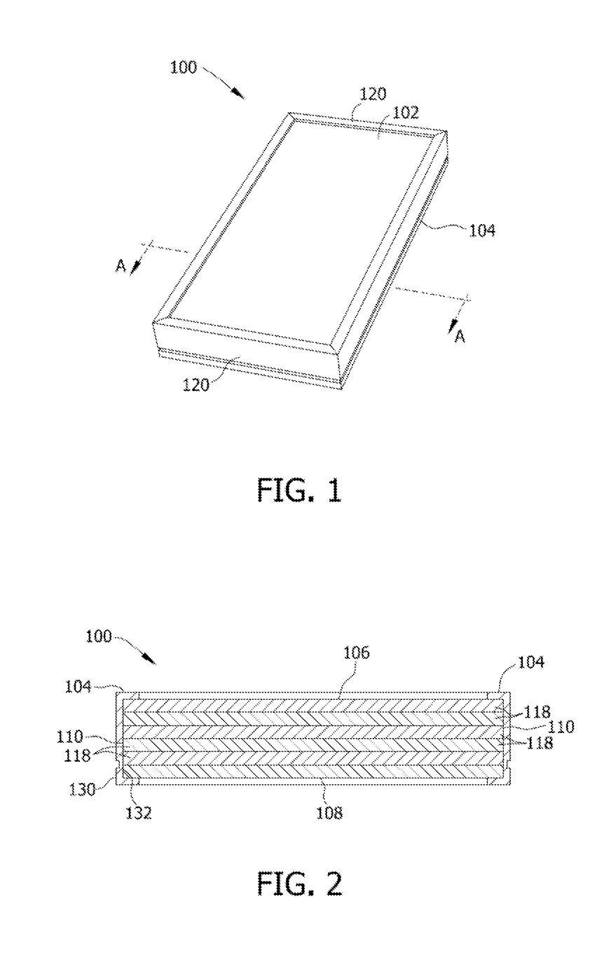

Referring initially to FIGS. 1 and 2, a PV module is indicated generally at 100. A perspective view of the PV module 100 is shown in FIG. 1. FIG. 2 is a cross sectional view of the PV module 100 taken at line A-A shown in FIG. 1. The PV module 100 includes a solar laminate 102 (also referred to as a PV laminate) and a frame 104 circumscribing the solar laminate 102.

The solar laminate 102 includes a top surface 106 and a bottom surface 108 (shown in FIG. 2). Edges 110 extend between the top surface 106 and the bottom surface 108. In this embodiment, the solar laminate 102 is rectangular shaped. In other embodiments, the solar laminate 102 may have any suitable shape.

As shown in FIG. 2, the solar laminate 102 has a laminate structure that includes several layers 118. Layers 118 may include for example glass layers, non-reflective layers, electrical connection layers, n-type silicon layers, p-type silicon layers, and/or backing layers. In other embodiments, solar laminate 102 may have more or fewer layers 118, including only one layer, or may have different layers 118, and/or may have different types of layers 118. The solar laminate 102 includes a plurality of solar cells (not shown), each of which converts solar energy to electrical energy. The outputs of the solar cells are connected in series and/or parallel to produce the desired output voltage and current for the solar laminate 102.

As shown in FIG. 1, the frame 104 circumscribes the solar laminate 102. The frame 104 is coupled to the solar laminate 102, as best seen in FIG. 2. The frame 104 assists in protecting the edges 110 of the solar laminate 102. In this embodiment, the frame 104 is constructed of four frame members 120. In other embodiments the frame 104 may include more or fewer frame members 120.

This frame 104 includes an outer surface 130 spaced apart from solar laminate 102 and an inner surface 132 adjacent solar laminate 102. The outer surface 130 is spaced apart from and substantially parallel to the inner surface 132. In this embodiment, the frame 104 is made of aluminum. More particularly, in some embodiments the frame 104 is made of 6000 series anodized aluminum. In other embodiments, the frame 104 may be made of any other suitable material providing sufficient rigidity including, for example, rolled or stamped stainless steel, plastic, or carbon fiber.

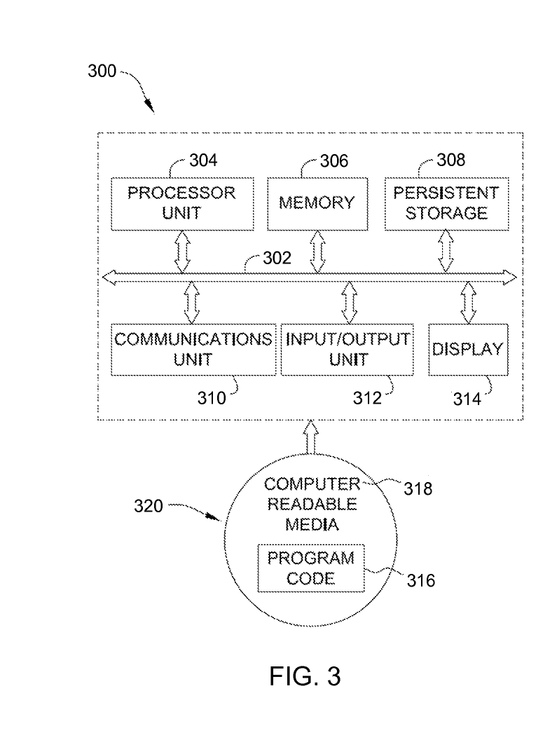

Some exemplary methods and systems are performed using and/or include computing devices. FIG. 3 is a block diagram of an exemplary computing device 300 that may be used. In the exemplary implementation, computing device 300 includes communications fabric 302 that provides communications between a processor unit 304, a memory 306, persistent storage 308, a communications unit 310, an input/output (I/O) unit 312, and a presentation interface, such as a display 314. In addition to, or in alternative to, the presentation interface may include an audio device (not shown) and/or any device capable of conveying information to a user.

Processor unit 304 executes instructions for software that may be loaded into a storage device (e.g., memory 306). Processor unit 304 may be a set of one or more processors or may include multiple processor cores, depending on the particular implementation. Further, processor unit 304 may be implemented using one or more heterogeneous processor systems in which a main processor is present with secondary processors on a single chip. In another implementation, processor unit 304 may be a homogeneous processor system containing multiple processors of the same type.

Memory 306 and persistent storage 308 are examples of storage devices. As used herein, a storage device is any tangible piece of hardware that is capable of storing information either on a temporary basis and/or a permanent basis. Memory 306 may be, for example, without limitation, random access memory (RAM) such as dynamic RAM (DRAM) or static RAM (SRAM), read-only memory (ROM), erasable programmable read-only memory (EPROM), electrically erasable programmable read-only memory (EEPROM), non-volatile RAM (NVRAM), and/or any other suitable volatile or non-volatile storage device. Persistent storage 308 may take various forms depending on the particular implementation, and persistent storage 308 may contain one or more components or devices. For example, persistent storage 308 may be one or more hard drives, flash memory, rewritable optical disks, rewritable magnetic tapes, and/or some combination of the above. The media used by persistent storage 308 also may be removable. For example, without limitation, a removable hard drive may be used for persistent storage 308.

A storage device, such as memory 306 and/or persistent storage 308, may be configured to store data for use with the processes described herein. For example, a storage device may store (e.g., have embodied thereon) computer-executable instructions, executable software components, PV system component data, PV system layouts, installation instructions, work orders, and/or any other information suitable for use with the methods described herein. When executed by a processor (e.g., processor unit 304), such computer-executable instructions and/or components cause the processor to perform one or more of the operations described herein.

Communications unit 310, in these examples, provides for communications with other computing devices or systems. In the exemplary implementation, communications unit 310 is a network interface card. Communications unit 310 may provide communications through the use of either or both physical and wireless communication links.

Input/output unit 312 enables input and output of data with other devices that may be connected to computing device 300. For example, without limitation, input/output unit 312 may provide a connection for user input through a user input device, such as a keyboard and/or a mouse. Further, input/output unit 312 may send output to a printer. Display 314 provides a mechanism to display information, such as any information described herein, to a user. For example, a presentation interface such as display 314 may display a graphical user interface, such as those described herein.

Instructions for the operating system and applications or programs are located on persistent storage 308. These instructions may be loaded into memory 306 for execution by processor unit 304. The processes of the different implementations may be performed by processor unit 304 using computer implemented instructions and/or computer-executable instructions, which may be located in a memory, such as memory 306. These instructions are referred to herein as program code (e.g., object code and/or source code) that may be read and executed by a processor in processor unit 304. The program code in the different implementations may be embodied in a non-transitory form on different physical or tangible computer-readable media, such as memory 306 or persistent storage 308.

Program code 316 is located in a functional form on non-transitory computer-readable media 318 that is selectively removable and may be loaded onto or transferred to computing device 300 for execution by processor unit 304. Program code 316 and computer-readable media 318 form computer program product 120 in these examples. In one example, computer-readable media 318 may be in a tangible form, such as, for example, an optical or magnetic disc that is inserted or placed into a drive or other device that is part of persistent storage 308 for transfer onto a storage device, such as a hard drive that is part of persistent storage 308. In a tangible form, computer-readable media 318 also may take the form of a persistent storage, such as a hard drive, a thumb drive, or a flash memory that is connected to computing device 300. The tangible form of computer-readable media 318 is also referred to as computer recordable storage media. In some instances, computer-readable media 318 may not be removable.

Alternatively, program code 316 may be transferred to computing device 300 from computer-readable media 318 through a communications link to communications unit 310 and/or through a connection to input/output unit 312. The communications link and/or the connection may be physical or wireless in the illustrative examples. The computer-readable media also may take the form of non-tangible media, such as communications links or wireless transmissions containing the program code.

In some illustrative implementations, program code 316 may be downloaded over a network to persistent storage 308 from another computing device or computer system for use within computing device 300. For instance, program code stored in a computer-readable storage medium in a server computing device may be downloaded over a network from the server to computing device 300. The computing device providing program code 316 may be a server computer, a workstation, a client computer, or some other device capable of storing and transmitting program code 316.

Program code 316 may be organized into computer-executable components that are functionally related. Each component may include computer-executable instructions that, when executed by processor unit 304, cause processor unit 304 to perform one or more of the operations described herein.

The different components illustrated herein for computing device 300 are not meant to provide architectural limitations to the manner in which different implementations may be implemented. The different illustrative implementations may be implemented in a computer system including components in addition to or in place of those illustrated for computing device 300. For example, in some embodiments, computing device includes a global positioning system (GPS) receiver. Moreover, components shown in FIG. 3 can be varied from the illustrative examples shown. As one example, a storage device in computing device 300 is any hardware apparatus that may store data. Memory 306, persistent storage 308 and computer-readable media 318 are examples of storage devices in a tangible form.

In another example, a bus system may be used to implement communications fabric 302 and may include one or more buses, such as a system bus or an input/output bus. Of course, the bus system may be implemented using any suitable type of architecture that provides for a transfer of data between different components or devices attached to the bus system. Additionally, a communications unit may include one or more devices used to transmit and receive data, such as a modem or a network adapter. Further, a memory may be, for example, without limitation, memory 306 or a cache such as that found in an interface and memory controller hub that may be present in communications fabric 302.

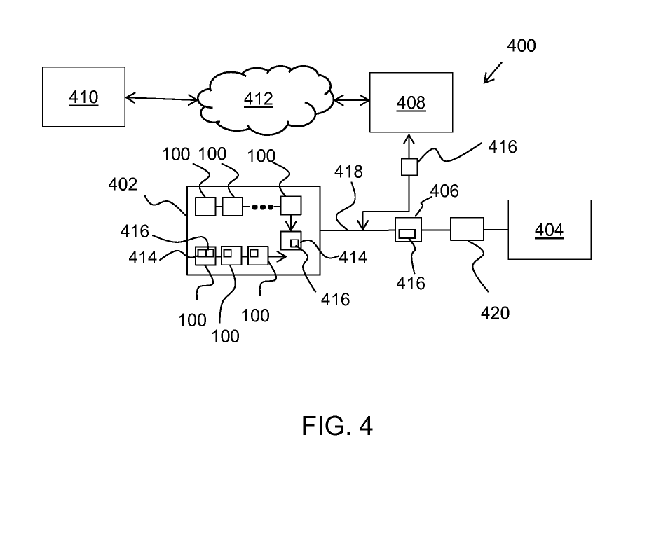

FIG. 4 is a block diagram of an exemplary PV solar system 400. The PV solar system 400 includes an array 402 of PV modules 100 and one or more inverters. The array 402 outputs AC power to one or more loads 404. A meter 406 measures the power delivered to the loads 404. In some embodiments, load 404 is an electric power grid. A gateway device 408, also referred to as a data acquisition device, monitors the array 402 and transmits data collected from the array 402 to a backend system 410 via a network 412.

The array 402 may be any suitable array of PV modules 100 and one or more inverters 414. For example, the array 402 may include a plurality of PV modules arranged in strings of PV modules. Each string of modules is connected to a single inverter to convert the DC output of the string of PV modules to an AC output. Alternatively, or additionally, each PV module may be coupled to its own inverter 414 (sometimes referred to as a microinverter) positioned near or on the PV module to which it is electrically coupled. In still other examples, a plurality of strings of PV modules may be connected, directly or through one or more string combiners, to a single inverter 414, sometimes referred to as a central or string inverter. In some embodiments, each inverter 414 is and/or includes a computing device, such as computing device 300.

In embodiments that do not include microinverters, the array 402 may include a direct current power manager/maximizer (DCPM) coupled to each PV module. In some embodiments, the DCPM is and/or includes a computing device, such as computing device 300. The DCPM performs, for example, maximum power point tracking (MPPT) for the PV module. It may also selectively control (i.e., limit and/or increase) the maximum power output of the PV module and/or control the conduction of bypass diodes based on temperature and bypass current. The DCPM may also translates the output I-V curve of the PV module to a new I-V curve at which the output voltage does not vary with ambient temperature.

In some embodiments, the array 402 includes one or more tracking devices configured to selectively position the PV modules relative to the sun to attempt to maximize the solar energy incident on the PV modules over time. Any other suitable arrangement of PV modules and inverter(s) may be used, including combinations of the arrangements described above.

PV system 400 includes several PLC modems 416. PLC modems 416 allow components with which they are connected to communicate data through power conductors that may also carry AC power. The PLC modems 416 are low-frequency narrow band modems utilizing a 70 kHz-150 kHz frequency band for communication. Alternatively, the PLC modems 416 are any other suitable PLC modem. In an example embodiment, PLC modems 416 are incorporated in, or are coupled in communication with, each inverter 414 in the system 400. Thus, inverters 416 may transmit data along the AC power conductors (e.g., conductor 418) connecting the output of inverters 414. Although conductor 418 is shown as a single line, it should be understood that conductor 418 may be any suitable number of conductors for power conduction within and between the PV system 400, the PV array 402, and the load 404. For example, conductor 418 is, in some embodiments, two phase conductors and a neutral conductor. In the example embodiment, meter 406 and gateway 408 are also communicatively coupled to, or incorporate, a PLC modem 416. Thus, in the example embodiment, inverters 416, meter 406, and gateway 408 may all communicate with each other over the power conductors to which the components are coupled. Other embodiments include other components coupled to, or incorporating a PLC modem 416. For example, one or more sensors (e.g., temperature sensor, pyranometer, etc.) may be coupled to a PLC modem 416. In at least one embodiment, the array 402 comprises a plurality of PV modules 100, each of which includes a microinverter 414 and a PLC modem coupled between the microinverter's communication output and the power output of the microinverter 414.

The gateway device 408 collects data concerning array 402, such as via one or more sensors (not shown). The gateway device 408 is and/or includes a computing device, such as computing device 300. The collected data may include any appropriate operational, situational, environmental, or other data related to the operation and/or condition of the array 402. For example, the gateway may monitor the ambient air temperature around the array 402, the amount of sunlight incident on the array 402 (or one or more PV module), the output voltage and current of the array 402, the output voltage and current of each PV module, the output voltage and current of each inverter and/or microinverter 414, the surface temperature of the PV modules 100, etc. Communication between sensors and the gateway device may be by PLC using one or more PLC modems 416.

Gateway device 408 communicates by PLC using PLC modems 416 with one or more components of the array 402. For example, the gateway device 408 communicates with inverters 414 in the array 402. Each inverter 414 may provide the gateway device 408 with, for example, its input voltage, its input current, its output voltage, its output current, and other suitable information. The information may be provided in response to a request from the gateway device 408 and/or at without a request from the gateway device 408 (e.g., periodically sent). In some embodiments, the array 402 (and more particularly the inverters 414) are controlled by the gateway device 408. In one example embodiment, the array 402 includes a plurality of PV modules 100, each of which includes a microinverter 414, and the gateway device 408 monitors, via PLC, the power transfer from the DC PV modules to the AC loads through each one of the inverters 414. In some embodiments, the inverters 414 feed the produced AC power differentially to a split phase AC grid 404, and the PLC modems 416 pass communication through the power conductors as a common mode signal between the neutral wire and the two phase conductors. In such embodiments, the neutral wire is only used for carrying PLC signals (i.e., AC power does not flow through the neutral wire when there are more than one phase, and the microinverters differentially feed AC power between phases).

In one example, the network 412 is the Internet. In other implementations, network 412 is any other suitable communication network, including, for example, a wide area network (WAN), a local area network (LAN), a cellular network, etc. Network 412 may include more than one network. For example, gateway device 408 may connect to the Internet through one or more other networks and/or interfaces, such as a local area network (LAN), a wide area network (WAN), a home area network (HAN), dial-in-connections, cable modems, high-speed ISDN lines and cellular modems.

A PLC filter 420 is coupled to conductor 418 between the PV system 400 and the grid 404. The PLC filter 420 isolates the PLC portion of the PV system 400 from the grid 404. Although shown as a separate component, PLC filter 420 may be integrated with a suitable component of PV system 400, including, for example, with meter 406. PLC filter 420 is a low pass filter that permits low frequency signals, including AC power, to pass freely between the PV system 400 and the grid 404. Higher frequency signals, however, are prevented from passing the filter 420. Thus, PLC signals produced in PV system 400 are not permitted to reach grid 404. Similarly, PLC signals produced by other systems connected to grid 404 may not pass filter 420 into PV system 400. Moreover, other relatively high frequency interference/noise present in the grid 404 is prevented from entering PV system 400. In an example embodiment, the PLC filter 420 is a low pass filter with a corner frequency at about 36 kHz, and has a stop-band attenuation of 62 dB at a frequency of 116 kHz. Alternatively, the PLC filter 420 may be a low pass filter with any other suitable characteristics. PLC filter 420 also separates the PV system 400 from the grid from a PLC communication perspective. The PLC modems only see a fifty ohm impedance, and do not see an impedance affected by the grid 404.

As described above, in an example system 400, each of the inverters 414 behaves as a true AC current source, whose output feeds differentially between the two phase conductors to the split-phase AC grid 404. The PLC modems 416 communicate via a common-mode signal between the neutral wire and both phase conductors. Hence, the example system does not utilize the neutral wire to pass AC power, and the neutral wire is used for PLC communication only. The low pass filter 420 includes inductors (not shown in FIG. 4) installed only on the neutral wire. By installing the inductors on the neutral wire, the inductors are not required to carry the heavy AC currents that present on the phase conductors.

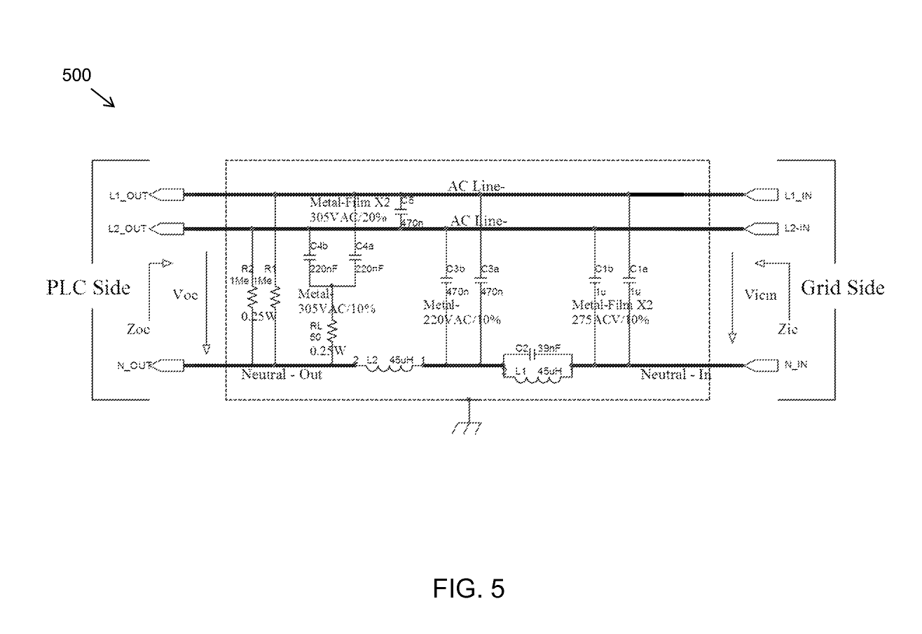

FIG. 5 is a circuit diagram of an example low pass filter 500 useable as the PLC filter 420. AC Lines L1 and L2 are the two phase conductors. The voltage between line L1 and the neutral line N and the voltage between line L2 and the neutral line N is 120 Vrms. The voltage between the lines L1 and L2 is 240 Vrms. When used in connection with the PV system 400, the grid side of the filter 500 is connected to grid 404, while the PLC side is coupled to PV system 400. Component values shown in FIG. 5 produce a low pass PLC filter 420 for coupling between a 60 Hz AC grid a PLC communication system transmitting common-mode signals between the neutral wire and both phase conductors L1 & L2.

As mentioned above, the inductors of PLC filter 420 (i.e., inductors L1 and L2) are installed on the neutral wire. Thus, they will not experience any heavy AC current through them and need only be designed to function under relatively low current (e.g., less than 0.5 A).

The one megaohm (MΩ) resistors R1 and R2 generally provide no filtering function. Rather, resistors R1 and R2 provide safety roll, to discharge the capacitors in the filter 500 from the Hi-Voltage they are charged to, when AC power is removed.

The 50Ω resistor RL, which is connected to the Neutral wire, and AC coupled to all phases (through 220 nF capacitors C4a and C4b) AC loads the COM Channel wires, and guarantee standard COM termination for the PLC modems 416. Thus, the PLC modems 416 see and need only drive a 50Ω impedance. Because the filter 500 provides a 50Ω impedance, less expensive PLC modems may be used in system 400. One of the reasons that more expensive PLC modems are generally used is due to the needed capability to drive low impedances, like <1Ω. Such scenarios actually happen in many houses, where a PLC gateway is installed closely to a Switched-Mode Power Supply, that has a large filtering capacitor between Phase & Neutral as part of an RFI/EMI Filter.

In one embodiment, inductors L1 and L2 are made of 4-AWG wire, capable of sustaining 40 amps (RMS) of 60 Hz AC current. The magnetic cores for inductors L1 and L2 are large enough to enable an 4-AWG wire, but magnetically are not saturated by any current lower then only 0.5 A·Turn. In order to achieve an inductance of about 50 μH, inductors L1 and L2 use either a high magnetic permeability (e.g., about μᵣ=2000-3000) with a relatively low number of turns (e.g., about 7-9) or a high number of turns with a low magnetic permeability.

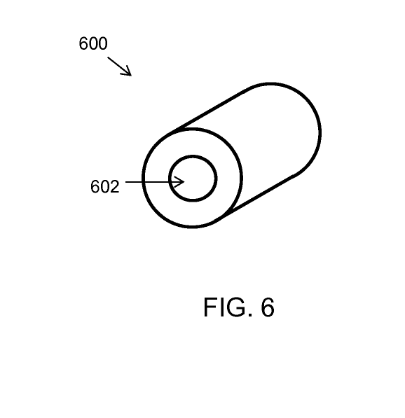

In another embodiment, the inductors L1 and L2 include low-frequency long-cylindrical ferrite beads for thick wire. FIG. 6 is an example of such a ferrite bead 600. Ferrite bead 600 is a hollow cylindrical shape made of ferrite material. Such ferrite beads are commonly used on a cable of wires to prevent conducted EMI. The wires pass through opening 602 in the ferrite bead 600, such that the ferrite material of the bead 600 surrounds the wires/cables. A ferrite bead 600 placed around the neutral wire provide an inductance that may be used as the inductor L1 or L2. Ferrite beads are available in different dimensions and made from different ferrite materials, which will provide different inductances when used with the neutral wire. Moreover, multiple ferrite beads 600 may be placed adjacent one another along the neutral wire to increase inductance presented to the neutral wire. By varying the type, size, and number of ferrite beads attached to the neutral wire, the desired inductances for inductors L1 and L2 may be achieved. In one example embodiment, the ferrite beads 600 are low frequency beads with a length of 28.58 mm, a diameter of 14.27 mm, and an opening 602 diameter of 6.35 mm. One suitable example ferrite bead 600 is part number LFB143064-000 available from Laird Technologies Inc. of Earth City, Mo., USA. In the example embodiment, each inductor L1 and L2 is made from two of the example ferrite beads 600 around the AWG-4 wire of the neutral line. Each pair of ferrite beads surrounding the neutral wire produces an equivalent inductance of 45 μH at 100 kHz-150 kHz.

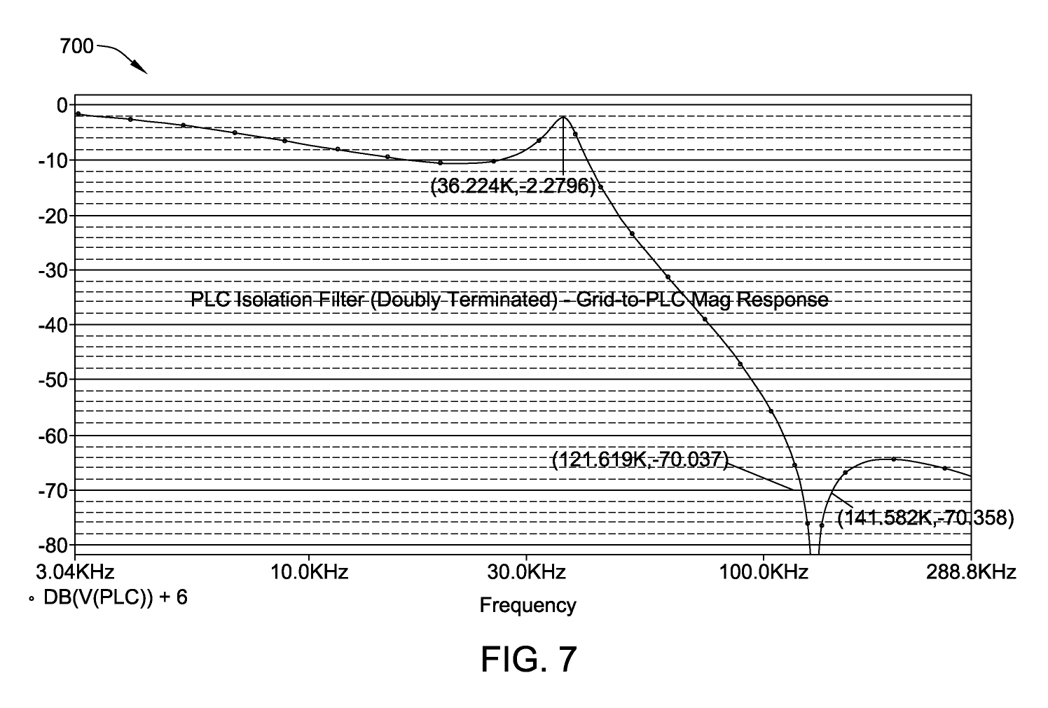

FIG. 7 is a graph 700 of the simulated frequency response of the filter 500 (shown in FIG. 5). The response represents the filter 500 behavior in the frequency domain with ideal inductors L1 and L2. In some embodiments, the inductors L1 and L2 are implemented using ferrite beads 600, which are lossy, resulting in the loss of the elliptic zero at 130 kHz. Moreover, if the ferrite beads 600 are very lossy, the above frequency response may change such that it is not monotonically decreasing at the stop-band (i.e., after 120 kHz). Thus, in some embodiments, the filter's stop-band attenuation may be limited to a few tens of decibels. However, reliable PLC communication can be achieved at low signal to noise ratios. Calculations and prototype tests confirm that filters 500 implemented using relatively lossy ferrite beads 600 can still achieve a stop band attenuation of greater than 20 dB (34 dB in at least one test), providing more than adequate signal to noise ratios for PLC communication.

The methods and systems of the present disclosure provide filtering for a PLC system. The example embodiments provide low pass filtration that permits low frequency AC signals to pass to the conductors to which PLC modems are coupled, but blocks high frequency noise and other interference. By coupling inductors only to a neutral wire, the example filters may utilize smaller and less expensive inductors. Moreover, some embodiments utilize inexpensive ferrite

This written description uses examples to disclose various embodiments, which include the best mode, to enable any person skilled in the art to practice those embodiments, including making and using any devices or systems and performing any incorporated methods. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense.

What is claimed is:

1. A low pass filter for power line communication in a power system including at least one phase conductor and a neutral conductor, the filter comprising:
at least one capacitor coupled between the phase conductor and the neutral conductor;
at least one resistor coupled between the phase conductor and the neutral conductor; and
at least one inductor coupled on the neutral conductor.

2. The low pass filter of claim 1, wherein the at least one inductor coupled on the neutral conductor is two inductors coupled on the neutral conductor.

3. The low pass filter of claim 2, wherein each inductor comprises a ferrite bead surrounding a portion of the neutral conductor.

4. The low pass filter of claim 3, wherein the ferrite bead comprises a cylindrical ferrite bead.

5. The low pass filter of claim 2, wherein each inductor comprises two or more ferrite beads surrounding a portion of the neutral conductor.

6. The low pass filter of claim 1, wherein the low pass filter has a corner frequency of about 36 kHz.

7. The low pass filter of claim 6, wherein the low pass filter has stop-band attenuation of 62 dB about at frequencies above 116 kHz.

8. The low pass filter of claim 1, wherein the at least one phase conductor is a first phase conductor and a second phase conductor.

9. The low pass filter of claim 8, wherein the at least one capacitor coupled between the phase conductor and the neutral conductor comprises at least one capacitor coupled between the first phase conductor and the neutral conductor and at least one capacitor coupled between the second phase conductor and the neutral conductor.

10. The low pass filter of claim 9, wherein the at least one resistor coupled between the phase conductor and the neutral conductor comprises at least one resistor coupled between the first phase conductor and the neutral conductor and at least one resistor coupled between the second phase conductor and the neutral conductor.

11. The low pass filter of claim 1, wherein the filter does not include an inductor coupled to the at least one phase conductor.

12. The low pass filter of claim 1, wherein the at least one resistor is coupled to the phase conductor through a capacitor.

13. A power line communication (PLC) system comprising:
a low pass filter configured for coupling between the PLC system and an alternating current (AC) grid, the low pass filter configured to create a relatively quiet line for PLC communication on a neutral conductor that does not carry AC current and to substantially isolate the PLC system from noise content of the AC grid.

14. The PLC system of claim 13, further comprising at least one PLC modem configured to pass communication as a common mode signal between the neutral conductor and at least one phase conductor.

15. The PLC system of claim 14, wherein the at least one PLC modem comprises a home-made PLC modem.

16. The PLC system of claim 14, wherein the at least one PLC modem is incapable of reliable PLC communication if the neutral conductor carries a significant amount of noise.

17. The PLC system of claim 14, wherein the at least one PLC modem is incapable of reliable PLC communication in the absence of the low pass filter.

18. A power line communication (PLC) system comprising:
a low pass filter configured for coupling between the PLC system and an alternating current (AC) grid, the low pass filter configured to substantially isolate the PLC system from noise content of the AC grid and to provide a fifty ohm termination for the PLC system.

19. The PLC system of claim 18, further comprising at least one PLC modem configured to pass communication as a common mode signal between the neutral conductor and at least one phase conductor.

20. The PLC system of claim 19, wherein the at least one PLC modem is incapable of providing PLC communication signals to a one ohm load.
